(19) United States
(12) Patent Application Publication
(10) Pub. No.: US 2025/0132538 A1
(43) Pub. Date: Apr. 24, 2025

(54) DISTRIBUTED FEEDBACK SEMICONDUCTOR LASER ASSEMBLY

(71) Applicants: HUAWEI TECHNOLOGIES CANADA CO., LTD., Kanata (CA); MCMASTER UNIVERSITY, Hamilton (CA)

(72) Inventors: Xun LI, Ancaster (CA); Chuanning NIU, Ottawa (CA); Manpo YANG, Hamilton (CA); Tan Huy HO, Stittsville (CA)

(21) Appl. No.: 18/490,498

(22) Filed: Oct. 19, 2023

(51) Int. Cl. H01S 5/12; H01S 5/183; H01S 5/30

(52) U.S. Cl. CPC H01S 5/1228; H01S 5/1209; H01S 5/18358; H01S 5/3054

(57) ABSTRACT

A distributed feedback (DFB) semiconductor laser assembly is disclosed. The DFB laser assembly includes a substrate extending along a longitudinal direction, a first electrode layer disposed on a first side surface thereof, an active region layer disposed on a second side surface thereof opposite the first side surface, and a spacer layer disposed on the active region layer. A ridge extends away from the active region layer and along the longitudinal direction. The DFB laser assembly also includes a grating layer integrated between the active region layer and the ridge, the grating layer including a plurality of sampled gratings along the longitudinal direction, and a second electrode layer electrically coupled to the first electrode layer, the second electrode layer comprising independent electrode sections disposed on the top ridge surface and each ridge side surface.

### CROSS-REFERENCE TO RELATED APPLICATIONS

This is the first application filed for the instantly disclosed technology.

### TECHNICAL FIELD

The present disclosure generally relates to the field of lasers and, in particular, to a distributed feedback semiconductor laser assembly.

### BACKGROUND

Wavelength tunable lasers, with flexible adjustment of the lasing wavelength, are essential components in wavelength division multiplexing (WDM) systems and wavelength routing networks. Driven by applications centered on cost effectiveness, tunable lasers are required not only to have a wide tuning range, but also to be modulated directly. Unfortunately, current broadband tunable lasers, including various external cavity tunable lasers and the Vernier effect based tunable distributed Bragg grating (DBR) laser, cannot be directly modulated at high-speed due to their long cavities. Another solution to the broadband tunable laser is the multiple wavelength distributed feedback (DFB) or DBR laser array, which can be modulated directly. However, an extra beam combiner or wavelength division multiplexer needs to be integrated with such a laser array to collect the light from different output port, and an extra semiconductor optical amplifier is often required to boost the output optical power for compensating the loss introduced by the combiner or multiplexer. Such a laser array has high fabrication complexity and low yield, and therefore is not generally a cost-effective solution.

Therefore, there remains an interest in developing systems that can fulfil the broadband wavelength tuning requirement and can be directly modulated at high-speed.

### SUMMARY

Distributed feedback semiconductor laser assembly are provided.

In accordance with a first broad aspect of the present disclosure, there is provided a distributed feedback (DFB) semiconductor laser assembly (i.e., DFB semiconductor laser assembly which is also called as DFB laser assembly for simplicity) including a substrate extending along a longitudinal direction, a first electrode layer disposed on a first side surface the substrate, an active region layer disposed on a second side surface of the substrate, the second side surface being opposite the first side surface and a spacer layer disposed on the active region layer. The laser assembly also includes a ridge extending away from the active region layer and along the longitudinal direction, a surface of the spacer layer including a top ridge surface extending along a top of the ridge and a ridge side surface defined on each lateral side of the ridge. The DFB laser assembly also includes a grating layer integrated between the spacer layer and the ridge, the grating layer including a plurality of sampled gratings along the longitudinal direction and a second electrode layer electrically coupled to the first electrode layer, the second electrode layer including independent electrode sections disposed on the top ridge surface and each ridge side surface.

In some non-limiting implementations, the ridge is centered with respect to the spacer layer, and the electrode sections of the second electrode layer are aligned with the sampled gratings such that each sample grating extends along a first electrode section disposed on a first ridge side surface, a second electrode section disposed on a second ridge side surface, the first and second electrode sections being short-circuited, and at least a portion of a third electrode section disposed on the top ridge surface.

In some non-limiting implementations, the sampled gratings have different sampling periods.

In some non-limiting implementations, the DFB laser assembly further includes a controller configured to cause distribution of electric power to the first and second electrode layers, and adjust an amount of electric current flowing between the electrode sections disposed on the top ridge surface and the first electrode layer to provide bias to the DFB laser assembly.

In some non-limiting implementations, the spacer layer is a p-type doped spacer layer extending between the active region layer and the grating layer.

In some non-limiting implementations, the plurality of sampled gratings includes a first sampled grating and a second sampled grating.

In some non-limiting implementations, the DFB laser assembly further includes a controller configured to cause distribution of electric power to the first and second electrode layers, and adjust an amount of electric current flowing between the electrode sections disposed on the bottom ridge section and the first electrode layer to modify refractive indexes of the first and second grating layers in an independent manner.

In some non-limiting implementations, the grating layer defines a base Bragg grating, the first sampled grating and the second sampled grating being periodic spatial samples of the base Bragg grating.

In some non-limiting implementations, the base Bragg grating has a base grating period of 228 nm, a base duty cycle of 0.5, and a base effective index of 3.4. The first sampled grating has a first sampling period of 71 nm, a first duty cycle of 0.2, and a first length along the main direction of 500 μm. The second sampled grating has a second sampling period of 59 nm, a second duty cycle of 0.125, and a second length along the main direction of 420 μm.

In some non-limiting implementations, the first and second sampled gratings are dual-sampled gratings and the base Bragg grating has a base grating period of 242 nm, a base duty cycle of 0.5, a first base index of 3.211, and a second base index of 3.2. The first sampled grating has a first sampling period of 25.1 nm with a first duty cycle of 0.5, a second sampling period of 16.7 nm with a second duty cycle of 0.5, and a first length along the main direction of 200 μm. The second sampled grating has a third sampling period of 21.9 nm with a third duty cycle of 0.5, a fourth sampling period of 14.6 nm with a fourth duty cycle of 0.5, and a second length along the main direction of 250 μm.

In some non-limiting implementations, the DFB laser assembly further defines isolation trenches along side walls the ridge, the isolation trenches being defined through the electrode sections of the second electrode layer disposed on the ridge side surfaces, the grating layer and a portion the spacer layer.

In some non-limiting implementations, a depth of the isolation trenches is between 40 nm and 60 nm.

In some non-limiting implementations, the grating layer includes a first grating layer section, a second grating layer section, and a continuous material portion connecting the first grating layer section to the second grating layer section.

### BRIEF DESCRIPTION OF THE FIGURES

Further features and advantages of the present disclosure will become apparent from the following detailed description, taken in combination with the appended drawings, in which:

FIG. 1 is a perspective view of a laser assembly in accordance with some implementations of the present technology;

FIG. 2 is a top plan view of the laser assembly of FIG. 1;

FIG. 3 is a side elevation view of the laser assembly of FIG. 1;

FIG. 4 is a cross-sectional view of the laser assembly of FIG. 1, taken along line 4-4 of FIG. 2;

FIG. 5 is a schematic diagram of spatial periodic pattern of a grating layer of the laser assembly of FIG. 1;

FIG. 6 is a cross-section view of the grating layer of the laser assembly of FIG. 1, taken along line 6-6 of FIG. 3;

FIG. 7 is a cross-sectional view of a grating layer of another non-limiting implementation of a laser assembly; and

FIG. 8 is cross-sectional view of a laser assembly in accordance with some other implementations of the present technology.

It is to be understood that throughout the appended drawings and corresponding descriptions, like features are identified by like reference characters. Furthermore, it is also to be understood that the drawings and ensuing descriptions are intended for illustrative purposes only and that such disclosures do not provide a limitation on the scope of the claims. It should also be noted that, unless otherwise explicitly specified herein, the drawings are not to scale.

### DETAILED DESCRIPTION

As used herein, the term “about” or “approximately” refers to a +/−10% variation from the nominal value. It is to be understood that such a variation is always included in a given value provided herein, whether or not it is specifically referred to.

Unless otherwise defined or indicated by context, all technical and scientific terms used herein have the same meaning as commonly understood by one of ordinary skill in the art to which the described implementations appertain to. The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

In the context of the present specification, unless provided expressly otherwise, the words “first”, “second”, “third”, etc. have been used as adjectives only for the purpose of allowing for distinction between the nouns that they modify from one another, and not for the purpose of describing any particular relationship between those nouns. Thus, for example, it should be understood that, the use of the terms “first processor” and “third processor” is not intended to imply any particular order, type, chronology, hierarchy or ranking (for example) of/between the processor, nor is their use (by itself) intended to imply that any “second processor” must necessarily exist in any given situation. Further, as is discussed herein in other contexts, reference to a “first” element and a “second” element does not preclude the two elements from being the same actual real-world element. Thus, for example, in some instances, a “first” processor and a “second” processor may be the same software and/or hardware, in other cases they may be different software and/or hardware.

It will be understood that when an element is referred to as being “connected” or “coupled” to another element, it can be directly or indirectly connected or coupled to the other element or intervening elements that may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In the context of the present specification, when an element is referred to as being “associated with” another element, in certain implementations, the two elements can be directly or indirectly linked, related, connected, coupled, the second element employs the first element, or the like without limiting the scope of the present disclosure.

The terminology used herein is only intended to describe particular representative implementations and is not intended to be limiting of the present technology. As used herein, the singular forms “a,” “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

With these fundamentals in place, the instant disclosure is directed to address at least some of the deficiencies of the current technology. In particular, the instant disclosure describes a laser assembly that has a relatively short cavity to realize high-speed direct modulation, the reduction of said cavity being possible by overlapping grating sections of the laser assembly with a gain section thereof as will be described in greater detail herein after.

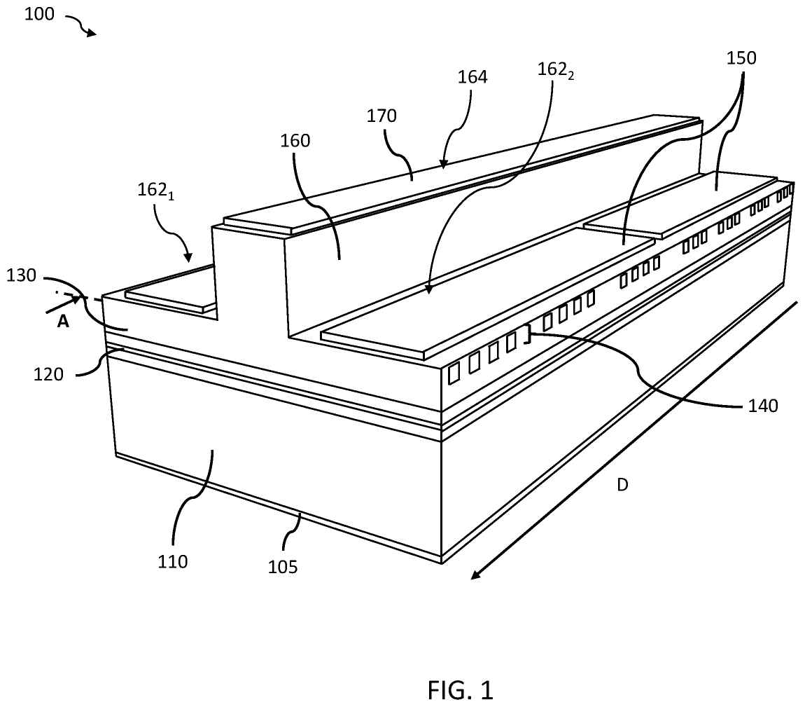

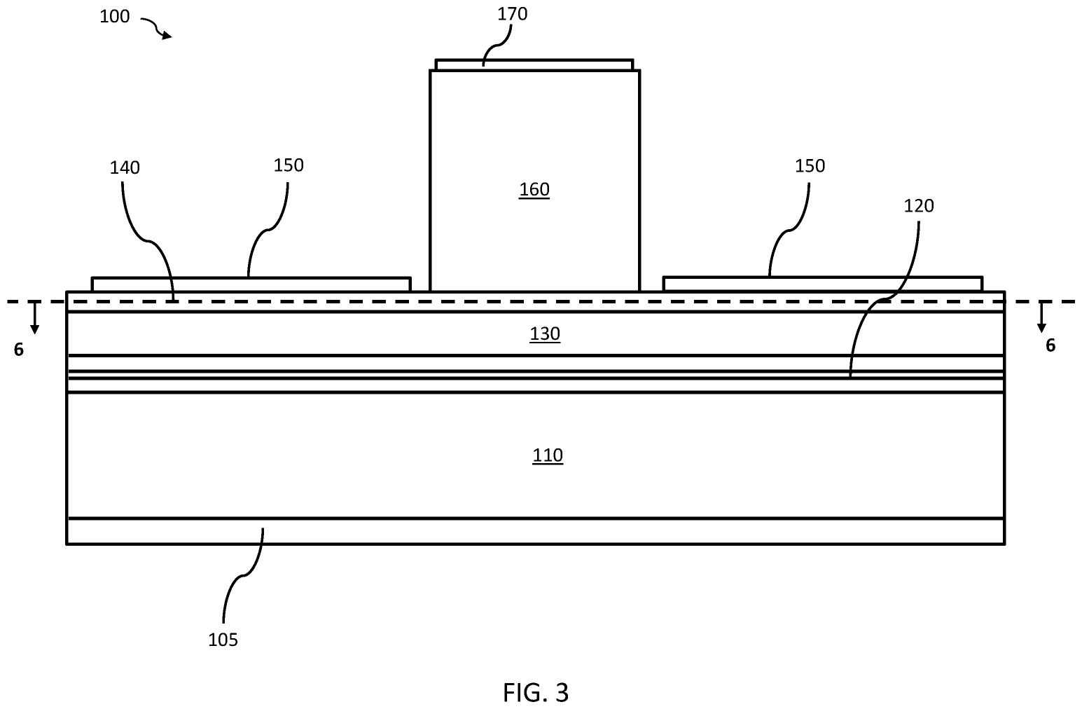

With reference to FIGS. 1 to 3, a laser assembly 100 according to one non-limiting implementation is illustrated. The laser assembly 100 includes a substrate 110 substantially extending along a longitudinal direction D, a first electrode layer 105 disposed on a first side of the substrate 110 and an active region layer 120 disposed on a second, opposite side of the substrate 110. The laser assembly 100 further includes a spacer layer 130 disposed on the active region layer 120 such that the active region layer 120 is sandwiched between the substrate 110 and the spacer layer 130. For example and without limitation, the active region layer 120 may include a semiconductor material such gallium arsenide (GaAs) or indium gallium arsenide (InGaAs). In this implementation, the active region layer 120 provides the gain for the laser assembly 100 and is sandwiched between a lower and an upper Graded-Index Separate Confinement Heterostructure (GRINSCH) layer.

In this implementation, the spacer layer 130 is a p-type doped spacer layer that, in use, aids in confining optical field and carriers within the active region. The spacer layer 130 may be made of a wide bandgap, low refractive index material, such as InP or GaAs.

The active region layer 120 includes quantum wells and barriers and may be made of InGaAsP or AlGaInAs. The GRINSCH layers are placed on both sides of the active region and help to confine the optical mode to the active region while minimizing the losses and provides effective confinement of both electrons and holes within the active region layer 120.

The laser assembly 100 also includes a ridge 160 extending away from the active region layer 120 and along the longitudinal direction D. The ridge 160 defines a top ridge surface 164 extending along a top of the ridge 160. Ridge side surfaces 162₁, 162₂ are defined on lateral sides of the ridge 160. Therefore, a surface of the spacer layer 130 includes the top ridge surface 164 and the ridge side surfaces 162₁, 162₂. In this implementation, the ridge 160 is relatively centered with respect to the spacer layer 130. In use, the ridge 160 forms a waveguide that confines the optical mode and provides carrier confinement for the active region layer 120. In some implementations, the width of the ridge 160 is between 1.6 and 2 μm, and a width of the substrate 110 is 250 μm. In some implementations, the ridge 160 is formed by etching a cladding and cap layers above the grating layer 140, with the material of the cladding layer typically being same as that of the spacer layer 130.

The laser assembly 100 also includes a grating layer 140 implemented in the spacer layer 130 and used to select a lasing wavelength of the laser assembly 100. More specifically, the grating layer 140 is integrated between the active region layer 120 and each ridge side surfaces 162₁, 162₂. The grating layer 140 defines a plurality of grating sections, two of which are depicted in FIG. 1. In this non-limiting example, the grating layer 140 defines a first grating section 140₁ and a second grating section 140₂ consecutive to the first grating section 140₁ along the direction D.

The laser assembly 100 further includes a second electrode layer electrically coupled to the first electrode layer 105. The second electrode layer includes independent electrode sections disposed on the top ridge surface 164 and each ridge side surface 162₁, 162₂. More specifically, the second electrode layer includes a top ridge electrode section 170 disposed on the top ridge surface 164, and ridge side electrode sections 150 disposed on the ridge side surfaces 162₁, 162₂. In this implementation, the first electrode layer 105 is a N-electrode and the second electrode layer is a P-electrode.

The following chart includes non-limiting examples of composition, thickness and doping of components of the laser assembly 100 from the substrate 110 to the ridge 160:

| | | Thickness | Doping |
|---|---|---|---|
| Layer | Composition | (nm) | (10¹⁸/cm³) |
| Substrate 110 | InP | 350,000 | (S) 3.0 |
| Buffer | InP | 300 | (Si) 1.5 |
| GRINSCH | Al_{0.47-x}GaₓIn_{0.53}As_{x=0.10~0} | 10 | (Si) 0.7 |
| layer | Al_{0.47}In_{0.53}As | 50 | (Si) 0.7 |
| | Al_{0.47-x}GaxIn_{0.5}As_{x=0~0.27} | 50 | UD |
| Barrier × 7 | Al_{0.20}Ga_{0.27}In_{0.53}As | 8 | UD |
| Well × 6 | Al_{0.31}Ga_{0.16}In_{0.53}As | 5 | UD |
| GRINSCH layer | Al_{0.47-x}GaxIn_{0.53} As_{x=0.27~0} | 50 | UD |
| | Al_{0.47}In_{0.53} As | 30 | (Zn) 1.0 |
| | Al_{0.47-x}GaxIn_{0.53}As_{x=0~0.10} | 10 | (Zn) 1.0 |
| Spacer layer 130 | InP | 100 | (Zn) 1.0 |
| Grating layer 140 | In_{0.75}Ga_{0.25}AS_{0.54}P_{0.46} | 80 | (Zn) 1.5 |
| Cladding | InP | 1700 | (Zn) 1.5 |
| Cap | In_{0.75}Ga_{0.25}AS_{0.54}P_{0.46} | 25 | (Zn) 3.0 |
| | In_{0.61}Ga_{0.39}AS_{0.84}P_{0.16} | 25 | (Zn) 3.0 |
| | In_{0.53}Ga_{0.47}As | 150 | (Zn) 30.0 |

In this implementation, the ridge 160 includes a cladding and a cap, non-limiting examples of materials thereof being disclosed in the chart above.

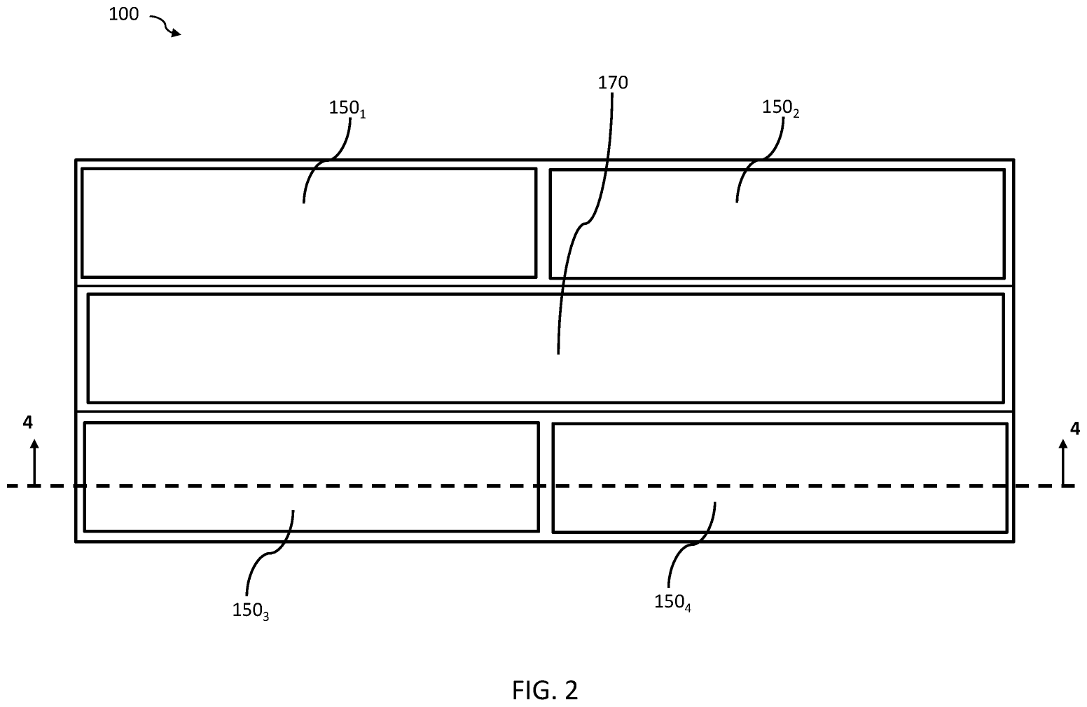

As best shown on FIG. 2, the top ridge electrode section 170 extends substantially along an entirety of the ridge 160. In this implementation, the second electrode layer includes four ridge side electrode sections 150₁, 150₂, 150₃ and 150₄. More specifically, the ridge side electrode section 150₁ extends substantially along a first half of the ridge side surfaces 162₁ and the ridge side electrode section 150₂ extends substantially along a second half thereof. The ridge side electrode sections 150₁, 150₂ are thus consecutive to one another along the longitudinal direction D. Similarly, the ridge side electrode section 150₃ extends substantially along a first half of the ridge side surfaces 162₂ and the ridge side electrode section 150₄ extends substantially along a second half thereof. The ridge side electrode sections 150₃, 150₄ are thus consecutive to one another along the longitudinal direction D.

In use, the top ridge electrode section 170 and the first electrode layer 105 are connected to an external source of electricity to provide bias to the laser assembly 100. The ridge sides electrode sections 150 and the first electrode layer 105 are connected to another external source of electricity to supply the current injection for changing the material refractive indices of the grating layer 140, which tunes the lasing wavelength of the laser assembly 100.

Therefore, it can be said that the laser assembly 100 exploits a distributed feedback (DFB) scheme while the active region layer 120 and the grating layer 140 are stacked one atop the other. As such, a phase adjustment section present in standard laser assemblies may no longer be required in the laser assembly 100. As a result, a laser cavity length of the laser assembly 100 is significantly reduced, which enables high-speed direct modulation of the laser assembly 100.

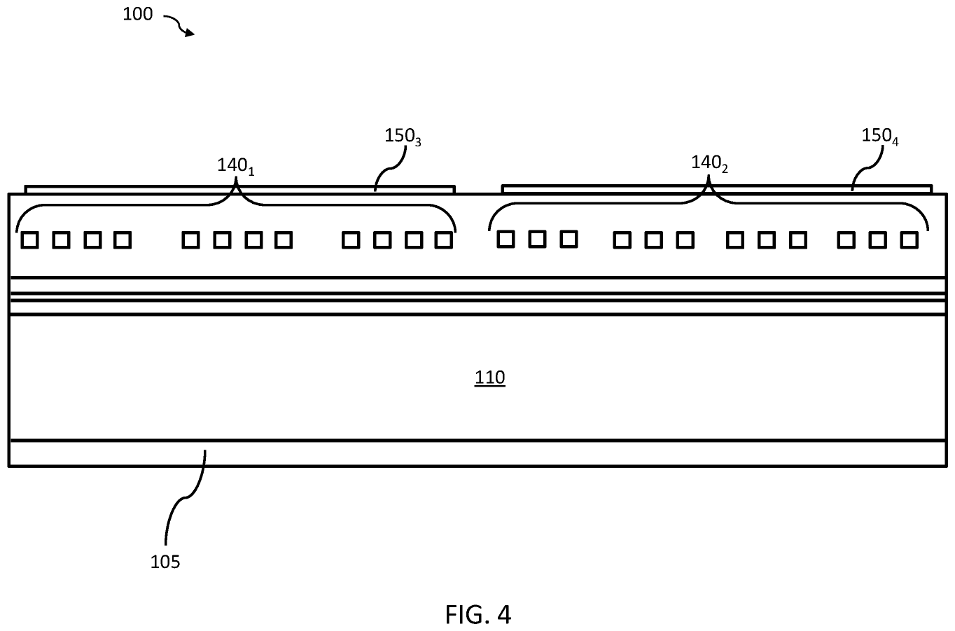

More specifically, in this implementation and as best shown on FIG. 4, the grating layer 140 includes a first and a second sampled gratings 140₁, 140₂ consecutive to one another along the longitudinal direction D. Different numbers of sampled gratings are contemplated in alternative implementations. For example, the grating layer 140 could include three consecutive sampled gratings. Broadly speaking, a sampled grating is a conventional grating with grating elements removed in a periodic fashion. This periodic modulation leads to reflection spectra with periodic maxima. It should be noted that the sampled gratings 140₁, 140₂ have different sampling periods, and thus have different free spectral ranges (FSR). The laser assembly 100 can thus still be tuned over a broad range through the Vernier effect.

In other words, the wavelength of the laser assembly 100 can be tuned over a broad band wavelength range through the Vernier effect. It can be said that the present technology exploits DFB scheme and the active region layer 120 and the grating layer 140 are stacked in the vertical direction. As a result, the laser cavity length is significantly reduced, and the reduced cavity length then enables the high-speed direct modulation of the laser assembly 100.

The pair of ridge side electrode sections 150₁, 150₃ are located above the first sampled grating 140₁, and the pair ridge side electrode sections 150₂, 150₄ are located above the second sampled grating 140₂. In other words, the ridge side electrode sections 150₁, 150₂, 150₃ and 150₄ are disposed beside the two sidewalls of the ridge 160. In this implementation, each pair of the ridge side electrode sections (150₁, 150₃ and 150₂, 150₄) are electronically short-circuited so that the same amount of current is injected into the corresponding sampled grating (140₁, 140₂ respectively) on both sides during operation. However, a gap is provided between the ridge side electrode sections located on a same side of the ridge 160, so that the current injected into the two sampled gratings 140₁, 140₂ can be adjusted in an independent manner. By controlling the amount of current flowing through between the ridge side electrode sections 150₁, 150₂, 150₃ and 150₄ and the first electrode layer 105, the refractive index of the grating layer 140 can be modified, which consequently shifts the wavelength of the spectra maxima of the sampled gratings 140₁, 140₂. Hence, the lasing wavelength of the laser assembly 100 can be tuned. In other words, it can be said that a pair of ridge side electrode sections is provided above each of the sampled gratings to separately change the material refractive indices of the sampled gratings. Therefore, in this implementation, the current injection to the active region layer 120 and the two tuning currents can be applied independently.

In some other implementations, the first and second sampled gratings 140₁, 140₂ are mono-sampled gratings formed from a base Bragg grating with Λ₀=228 nm, with a duty cycle p₀=0.5 and an effective n_{eff}=3.4. The first sampled grating 140₁ is formed by sampling said base Bragg grating with a spatial period of Λ₁=71 μm with a duty cycle p₁=0.2, a length of the first sampled grating 140₁ being L₁=500 μm. The second sampled grating 140₂ is formed by sampling said base Bragg grating with a spatial period of Λ₂=59 μm with a duty cycle p₂=0.125, a length of the second sampled grating 140₂ being L₂=420 μm. In some implementations, the length of a given sampled grating 140₁ or 140₂ is around 8 to 10 times the corresponding sampling spatial period Λ₁, Λ₂.

With the above parameters, the center wavelengths of the first and second sampled gratings 140₁, 140₂ are about at λ_{B}=1550 nm. The FSR of the first sampled grating 140₁ (FSR₁) is about 5 nm and the FSR of the second sampled grating 140₂ (FSR₂) is about 6 nm. According to the working principle of the Vernier effect, lasing occurs at that pair of maxima that are aligned. In this implementation, the lasing wavelength is about 1542 nm. By change the current or voltage between the ridge side electrode sections 150₁, 150₂, 150₃ and 150₄ and the first electrode layer 105, the maxima of the spectra can shift. If the spectra of the first and second sampled gratings 140₁, 140₂ are aligned at the location of +2 order, for example, the lasing wavelength of the laser assembly 100 will be about 1562 nm. The tuning range of the laser assembly 100 based on Vernier effect can be written as:

$$range = \vert \frac{{FSR}_{1} * {FSR}_{2}}{{FSR}_{1} - {FSR}_{2}} \vert .$$

In this implementation, the lasing wavelength can be continuously tuned over the range of 30 nm. Applying with the conventional sampled gratings, the total cavity length of the laser assembly 100 can be made less than 1000 μm. Consequently, the modulation bandwidth of the laser assembly 100 is in the range of 2˜4 GHz.

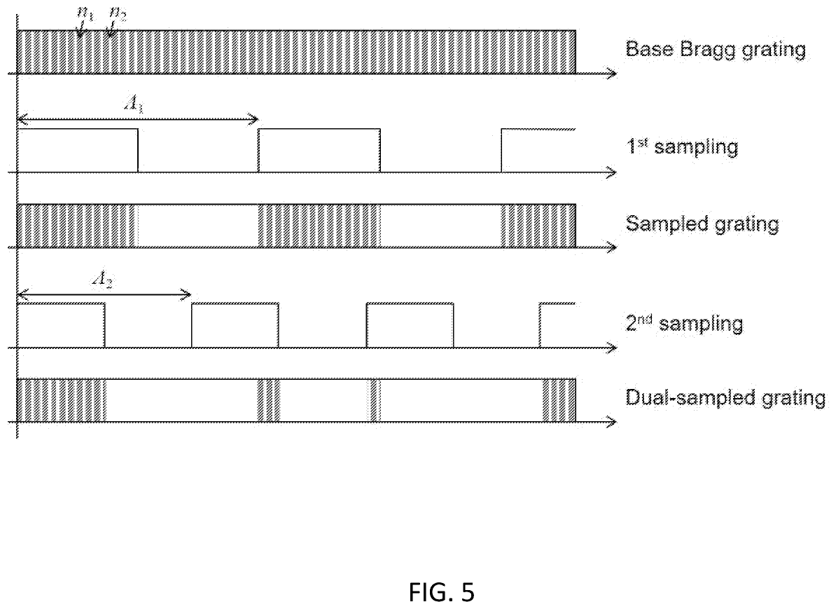

FIG. 5 shows a schematic diagram of spatial periodic pattern of the grating layer 140 in accordance with some implementations of the present technology. In this implementation, the sampled gratings 140₁, 140₂ are dual-sampled gratings and are formed by a base Bragg grating with a first refractive index n₁ and a second refractive index n₂. Said base Bragg grating is sampled with a spatial period of Λ₁ to form a first mono-sampled grating that is further sampled with a spatial period of Λ₂ to form the first sampled grating 140₁. In a similar manner, the base Bragg grating is sampled with a spatial period of Λ₁′ to form a second mono-sampled grating that is further sampled with a spatial period of Λ₂′ to form the second sampled grating 140₂. For example and without limitations, the grating period of the base Bragg grating may be Λ₀=242 nm, with a duty cycle p₀=0.5 and n₁=3.211, n₂=3.200. The spatial periods may be Λ₁=25.1 μm, with a duty cycle p₁=0.5, and Λ₂=16.7 μm, duty cycle p₂=0.5. A length of the first sampled grating 140₁ is L_{f}=200 μm. For the second sample grating 140₂, the spatial periods may be Λ₁=21.9 μm, with a duty cycle p₁′=0.5 and Λ₂=14.6 μm, with a duty cycle p₂′=0.5. A length of the second sampled grating 140₂ is Lᵣ=250 μm.

With the above parameters, central reflection wavelengths of the dual-sampled gratings 140₁, 140₂ are at λ_{B}=1550 nm and the adjacent wavelength spacing between the reflection peaks at orders of P_{0,0}, P_{±1,0}, P_{0,±1}, and P_{±}1,±1 (FSR) are Δλ_{f}=7 nm and Δλᵣ=8 nm. In this implementation, the lasing wavelength can be continuously tuned over a range of 56 nm. In addition, the total cavity length of the laser assembly 100 is about 550 μm and it can be directly modulated up to 6 Gbps.

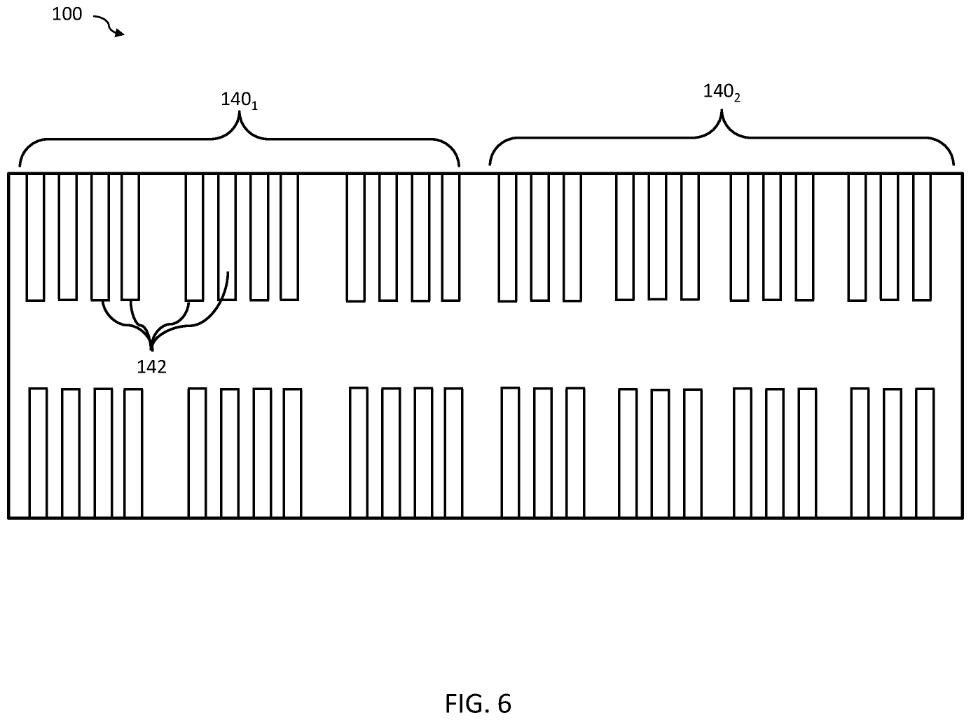

FIG. 6 is a cross-sectional view of the grating layer 140 of the laser assembly 100. In this implementation, teeth 142 of the sampled gratings 140₁, 140₂ are defined on both sides of the ridge 160 below the ridge side electrode sections 150₁, 150₂, 150₃ and 150₄. Material of the teeth 142 is only provided below the ridge side electrode sections and no grating material is provided directly below the ridge 160. In other words, it can be said that the grating layer 140 underneath the ridge 160 is completely removed. Therefore, the doping concentration underneath the ridge 160 may be reduced, thereby further minimizing the interference between the current injections.

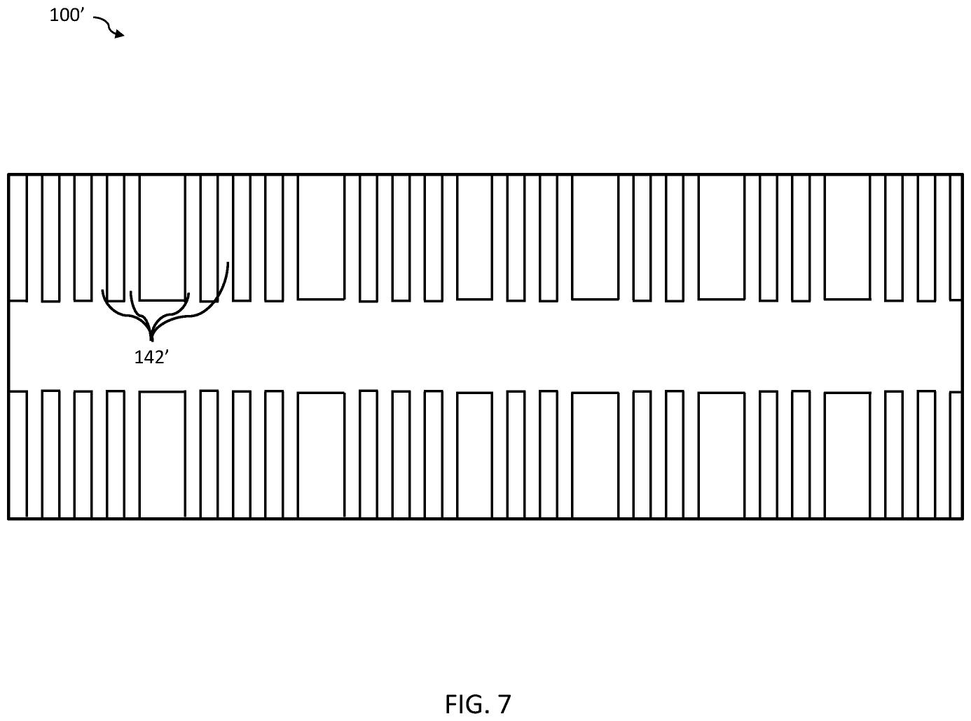

FIG. 7 is a cross-sectional view of a laser assembly 100′ in accordance with another implementation of the present technology, illustrating another implementation of a grating layer. In this implementation, material of the teeth 142′ extends below the ridge 160. The sampled gratings may thus be formed after the ridge is formed, which simplifies the fabrication process of the laser assembly 100. With such a design, the interference between the injections for gain and wavelength tuning may be minimized, as the current injection for gain may not go through the grating layer, and the lateral current leakage may also be reduced.

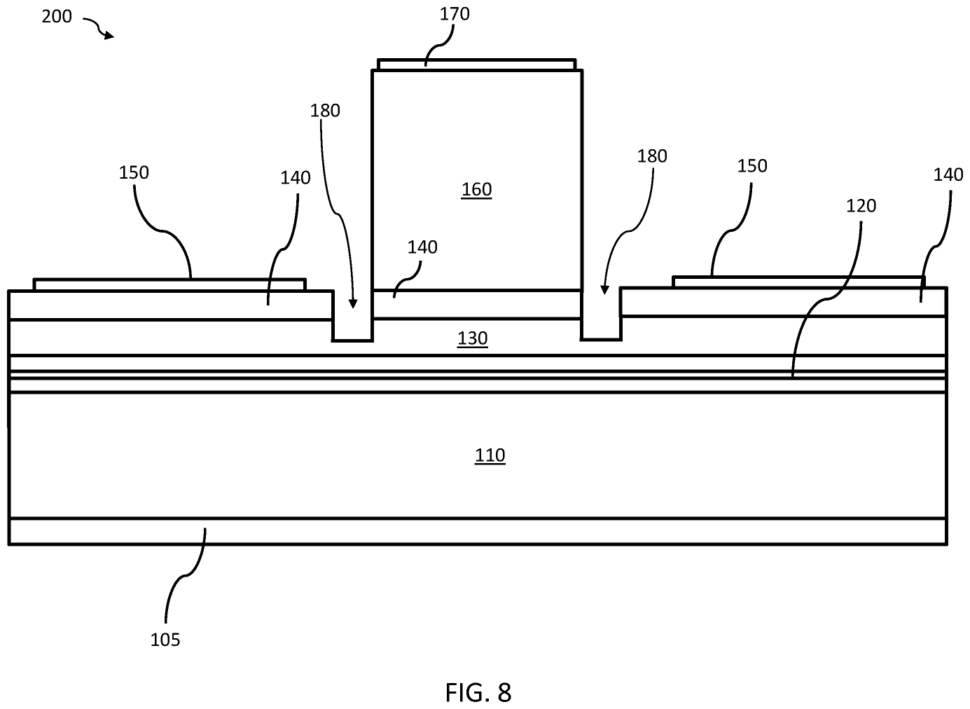

Another implementation of a laser assembly 200 according to the present technology is illustrated in FIG. 8. Elements of the laser assembly 200 that are similar to those of the laser assembly 100 retain the same reference numeral and will generally not be described again. The laser assembly 200 includes isolation trenches 180 defined along the ridge 160 and through the ridge side electrode sections 150, the grating layer 140 and a portion the spacer layer 130. The isolation trenches 180 are etched on each side of the ridge 160 and further passivated after etching. The width of isolation trenches 180 may be about 50 nm. The isolation trenches 180 may help in reducing the injection current leakage between the top ridge electrode section 170 and the ridge side electrode sections 150. The isolation trenches 180 may provide enhanced isolation among the top ridge electrode section 170 and the ridge side electrode sections 150 thereby reducing the interference between current injections for the gain of the laser assembly 100 and for lasing wavelength tuning. It should be noted that, given that the width of the isolation trenches 180 is less than a quarter of the operating wavelength, said isolation trenches 180 will not generally affect the lateral spreading of the laser transverse mode in a significant manner. Hence the confined optical field will still have a sufficient overlap with the grating layer 140 which provides the laser feedback and tuning.

It will also be understood that, although the implementations presented herein have been described with reference to specific features and structures, it is clear that various modifications and combinations may be made without departing from such disclosures. The specification and drawings are, accordingly, to be regarded simply as an illustration of the discussed implementations or implementations and their principles as defined by the appended claims, and are contemplated to cover any and all modifications, variations, combinations or equivalents that fall within the scope of the present disclosure.

What is claimed is:

1. A distributed feedback (DFB) semiconductor laser assembly comprising:
a substrate extending along a longitudinal direction;
a first electrode layer disposed on a first side surface the substrate;
an active region layer disposed on a second side surface of the substrate, the second side surface being opposite the first side surface;
a spacer layer disposed on the active region layer;
a ridge extending away from the active region layer and along the longitudinal direction, the ridge defining a top ridge surface extending along a top of the ridge and a ridge side surface defined on each lateral side of the ridge;
a grating layer integrated between the spacer layer and the ridge, the grating layer comprising a plurality of sampled gratings along the longitudinal direction, the plurality of sampled gratings having different sampling periods; and
a second electrode layer electrically coupled to the first electrode layer, the second electrode layer comprising independent electrode sections disposed on the top ridge surface and each ridge side surface.

2. The DFB semiconductor laser assembly of claim 1, wherein:
the electrode sections of the second electrode layer are aligned with the sampled gratings such that each sample grating extends along:
a first electrode section disposed on a first ridge side surface,
a second electrode section disposed on a second ridge side surface, the first and second electrode sections being short-circuited, and
at least a portion of a third electrode section disposed on the top ridge surface.

3. The DFB semiconductor laser assembly of claim 1, wherein the sampled gratings have different sampling periods.

4. The DFB semiconductor laser assembly of claim 1, further comprising a controller configured to:
cause distribution of electric power to the first and second electrode layers, and
adjust an amount of electric current flowing between the electrode sections disposed on the top ridge surface and the first electrode layer to provide bias to the DFB laser assembly.

5. The DFB semiconductor laser assembly of claim 1, wherein the spacer layer is a p-type doped spacer layer extending between the active region layer and the grating layer.

6. The DFB semiconductor laser assembly of claim 1, wherein the plurality of sampled gratings includes a first sampled grating and a second sampled grating.

7. The DFB semiconductor laser assembly of claim 6, further comprising a controller configured to:
cause distribution of electric power to the first and second electrode layers, and
adjust an amount of electric current flowing between the electrode sections disposed on the bottom ridge section and the first electrode layer to modify refractive indexes of the first and second grating layers in an independent manner.

8. The DFB semiconductor laser assembly of claim 6, wherein the grating layer defines a base Bragg grating, the first sampled grating and the second sampled grating being periodic spatial samples of the base Bragg grating.

9. The DFB semiconductor laser assembly of claim 8, wherein:
the base Bragg grating has:
a base grating period of 228 nm,
a base duty cycle of 0.5, and
a base effective index of 3.4,
the first sampled grating has:
a first sampling period of 71 nm,
a first duty cycle of 0.2, and
a first length along the main direction of 500 μm, and
the second sampled grating has:
a second sampling period of 59 nm,
a second duty cycle of 0.125, and
a second length along the main direction of 420 μm.

10. The DFB semiconductor laser assembly of claim 8, wherein the first and second sampled gratings are dual-sampled gratings and:
the base Bragg grating has:
a base grating period of 242 nm,
a base duty cycle of 0.5,
a first base index of 3.211, and
a second base index of 3.2,
the first sampled grating has:
a first sampling period of 25.1 nm with a first duty cycle of 0.5,
a second sampling period of 16.7 nm with a second duty cycle of 0.5, and
a first length along the main direction of 200 μm,
the second sampled grating has:
a third sampling period of 21.9 nm with a third duty cycle of 0.5,
a fourth sampling period of 14.6 nm with a fourth duty cycle of 0.5, and
a second length along the main direction of 250 μm.

11. The DFB semiconductor laser assembly of claim 1, further defining isolation trenches along side walls the ridge, the isolation trenches being defined through the electrode sections of the second electrode layer disposed on the ridge side surfaces, the grating layer and a portion the spacer layer.

12. The DFB semiconductor laser assembly of claim 11, wherein a depth of the isolation trenches is between 40 nm and 60 nm.

13. The DFB semiconductor laser assembly of claim 1, wherein the ridge is centered with respect to the spacer layer.

14. The DFB semiconductor laser assembly of claim 1, wherein:
the grating layer includes a first grating layer section, a second grating layer section, and a continuous material portion connecting the first grating layer section to the second grating layer section.
